(19) United States
(12) Patent Application Publication
(10) Pub. No.: US 2013/0119543 A1
(43) Pub. Date: May 16, 2013

(54) THROUGH SILICON VIA FOR STACKED WAFER CONNECTIONS

(71) Applicants: Hong YU, Singapore (SG); Huang LIU, Singapore (SG); Alex SEE, Singapore (SG)

(72) Inventors: Hong YU, Singapore (SG); Huang LIU, Singapore (SG); Alex SEE, Singapore (SG)

(73) Assignee: GLOBALFOUNDRIES Singapore Pte. Ltd., Singapore (SG)

(21) Appl. No.: 13/298,044

(22) Filed: Nov. 16, 2011

(51) Int. Cl. H01L 23/48; H01L 21/768

(52) U.S. Cl. 257/741; 438/667; 257/E21.586; 257/E23.011

(57) ABSTRACT

Stacked wafer connections are enhanced by forming a though silicon via including a first via portion formed in an upper portion of a via hole and a second via portion in a lower portion of the via hole. Embodiments include forming a via hole in a first surface of a substrate; partially filling the via hole with a dielectric material; filling the remainder of the via hole with a first conductive material; removing a portion of a second surface of the substrate to expose the dielectric material; removing the dielectric material from the via hole; and filling a the via hole with a second conductive material electrically conductively connected to the first conductive material.

### TECHNICAL FIELD

The present disclosure relates to semiconductor devices, and more particularly to stacked wafer connections.

### BACKGROUND

In order to interconnect stacked wafers, manufacturers have attempted various through silicon via (TSV) formation processes. However, conventional TSV processes have distinct drawbacks. For example, conventional via-first or via-middle TSV processes can cause a backside copper (Cu) contamination to a substrate during backside grinding, thinning, or cleaning processes. Thus, as shown in FIG. 4, formation of such a TSV 400 can result in contamination 402 on a backside of substrate 404, which can lead to reductions in reliability of the semiconductor device. Also, conventional via-last TSV schemes can cause punch-through of a pre-metal layer during TSV etch. Additionally, a high aspect-ratio TSV structure makes the deposition of conformal seed layers very challenging. Non-conformal copper seed layers have minimal sidewall coverage, and can lead to void formation during the subsequent copper TSV fill step, directly impacting device reliability.

Methods have been attempted in which a tapered TSV is formed, which can increase the subsequent physical vapor deposition (PVD) step coverage; however, such tapered TSV structures limit the ultimate packaging density that can be achieved. Methods have also been attempted that utilize thicker copper seed layers in order to achieve sufficient sidewall coverage within the TSV feature; however, such methods can result in an expensive manufacturing process due to a higher cost of consumables and lower system throughput.

A need therefore exists for methodology enabling the cost-effective fabrication of TSV structures that enhance reliability of stacked wafer connections.

### SUMMARY

An aspect of the present disclosure is a method of forming a TSV with high reliability.

Another aspect of the present disclosure is a TSV with high reliability.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming a via hole in a first surface of a substrate, partially filling the via hole with a dielectric material, filling the remainder of the via hole with a first conductive material, removing a portion of a second surface of the substrate to expose the dielectric material, removing the dielectric material from the via hole, and filling a the via hole with a second conductive material electrically conductively connected to the first conductive material

Another aspect of the present disclosure is a through silicon via including a first via portion formed of a first conductive material in a first via hole extending into a substrate from a first surface of the substrate, and a second via portion formed of a second conductive material in a second via hole extending into the substrate from a second surface of the substrate, wherein the second via portion is electrically conductively connected to the first via portion.

Yet another aspect of the present disclosure is a method including forming a via hole in a first surface of a silicon substrate, conformally depositing an isolation material in the via hole, forming a dummy plug in a lower portion of the via hole, depositing a liner material in an upper portion of the via hole, forming a first via portion using a first conductive material in the upper portion of the via hole, removing the second surface of the silicon substrate to expose a back surface of the dummy plug, removing the dummy plug from the lower portion of the via hole, forming an isolation material on the sidewalls of the lower portion of the via hole, depositing a liner material in the lower portion of the via hole, and forming a second via portion using a second conductive material in the lower portion of the via hole, wherein the second via portion is electrically conductively connected to the first via portion.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1M schematically illustrate a process flow for fabricating a TSV structure, according to an exemplary embodiment;

FIGS. 2A though 2C schematically illustrate a process flow for fabricating a TSV structure using alternative steps to the steps shown in FIGS. 1K through 1M, according to an exemplary embodiment;

FIG. 3 a flowchart of a process flow for fabricating a TSV structure, according to an exemplary embodiment; and

FIG. 4 is an illustration of a TSV structure formed using a related art process that results in contamination.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present invention provides a method of forming a TSV with high reliability. Embodiments of the invention provide numerous advantages. For example, with such embodiments, there is no concern for backside copper contamination, as can occur in conventional via-middle schemes, where a copper through silicon via will expose during the backside thinning and cleaning and thereby may contaminate the substrate. Also, the embodiments are very friendly to liner deposition or copper seed deposition, and copper electromechanical planarization, because the aspect ratio is reduced by half, which provides significant advantages to solve the TSV metallization challenges. Also, compared with conventional via-last scheme, embodiments of the invention can solve the punch-through issues, because the TSV etch is conducted before the back-side process. Further, embodiments of the invention are self-aligned and do not require an additional TSV mask.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

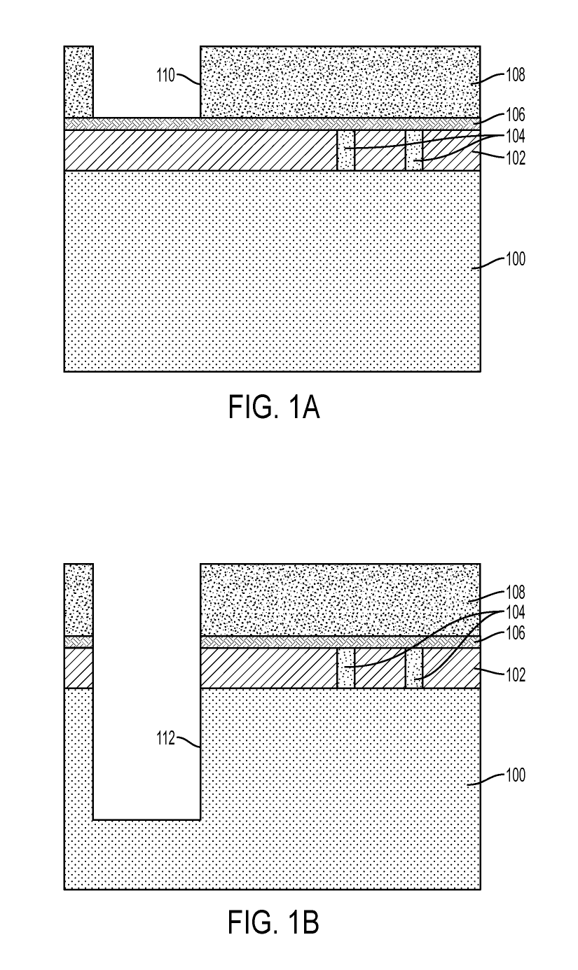

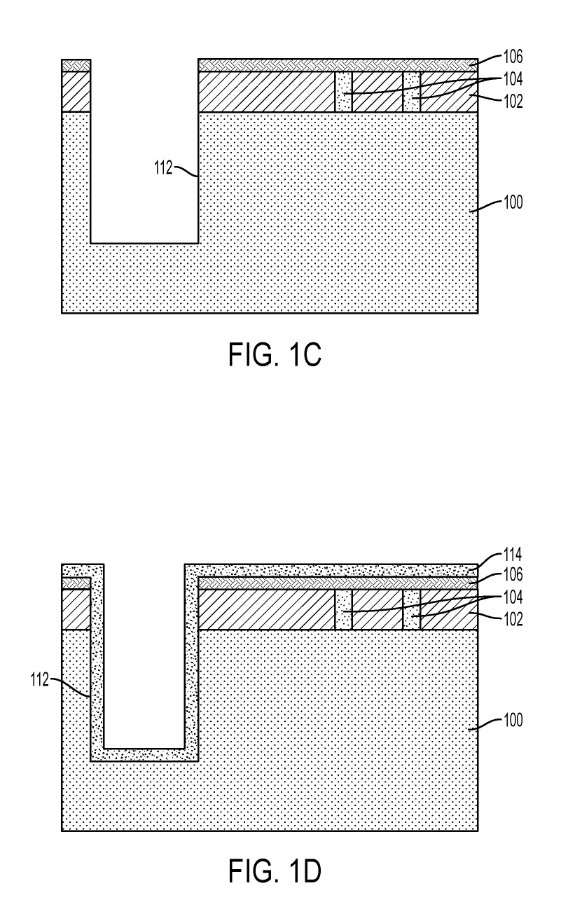

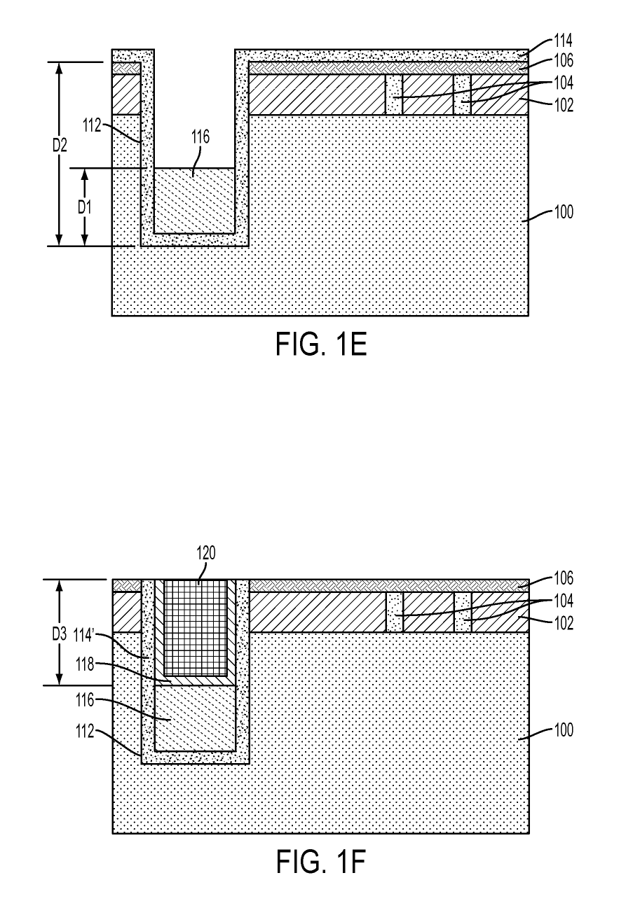

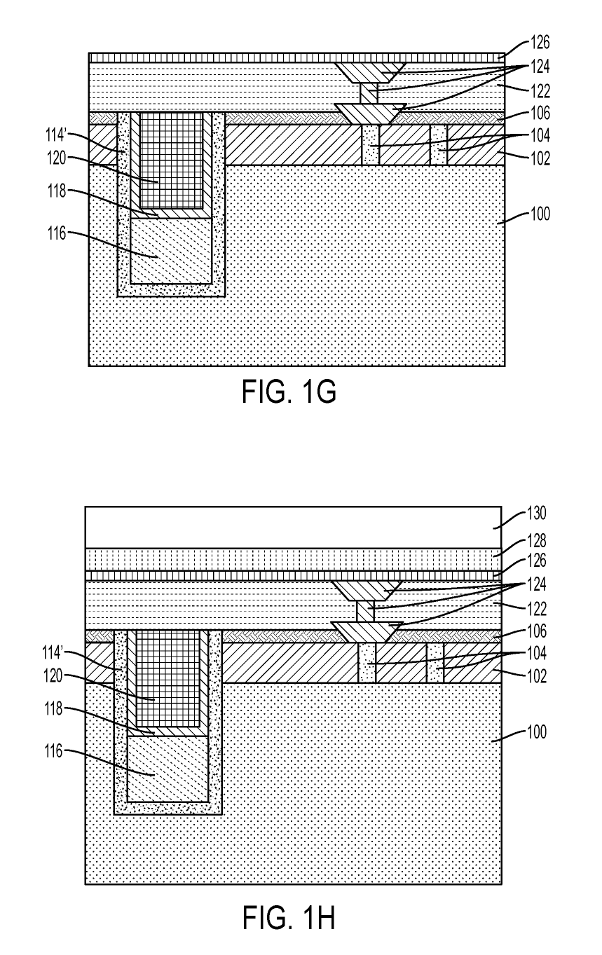

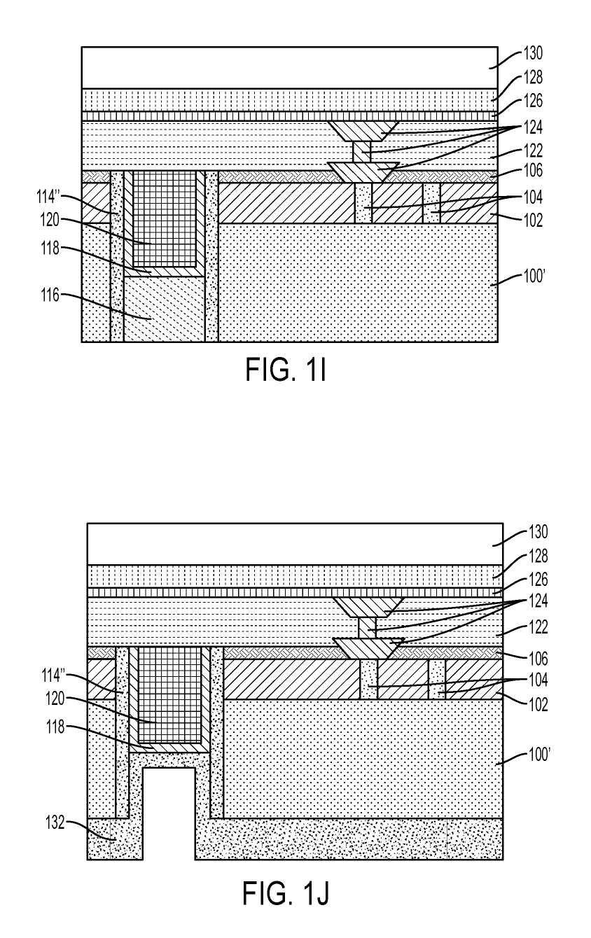

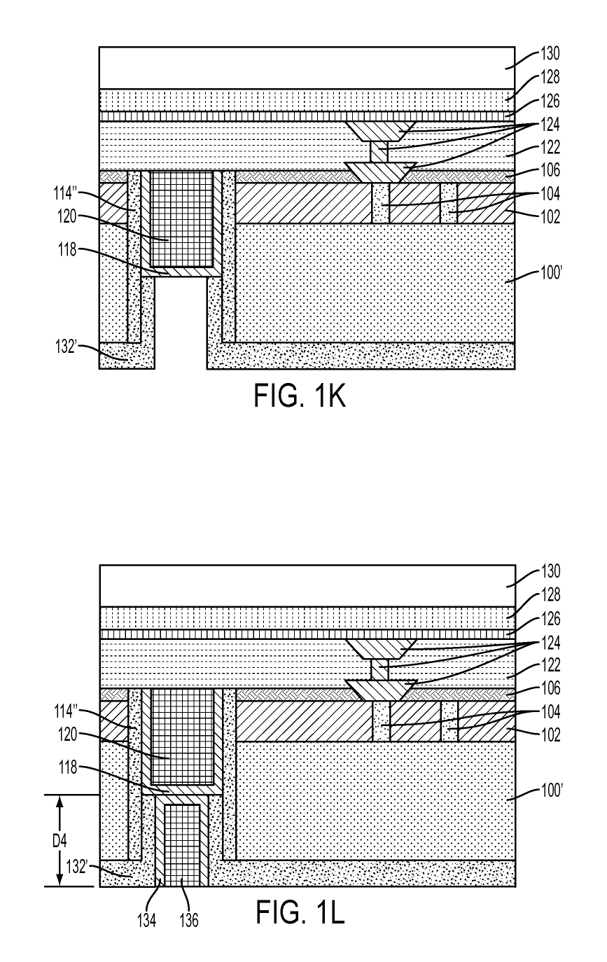

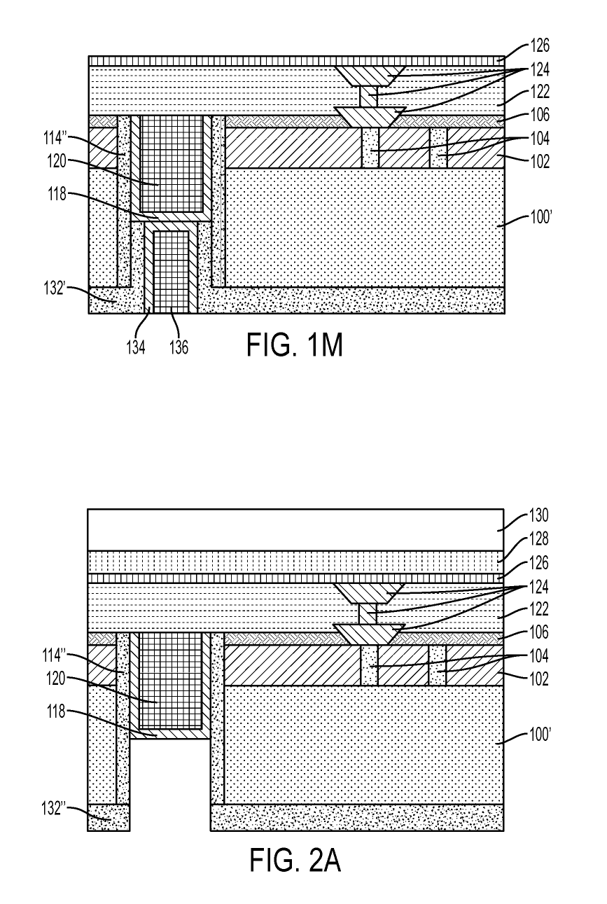

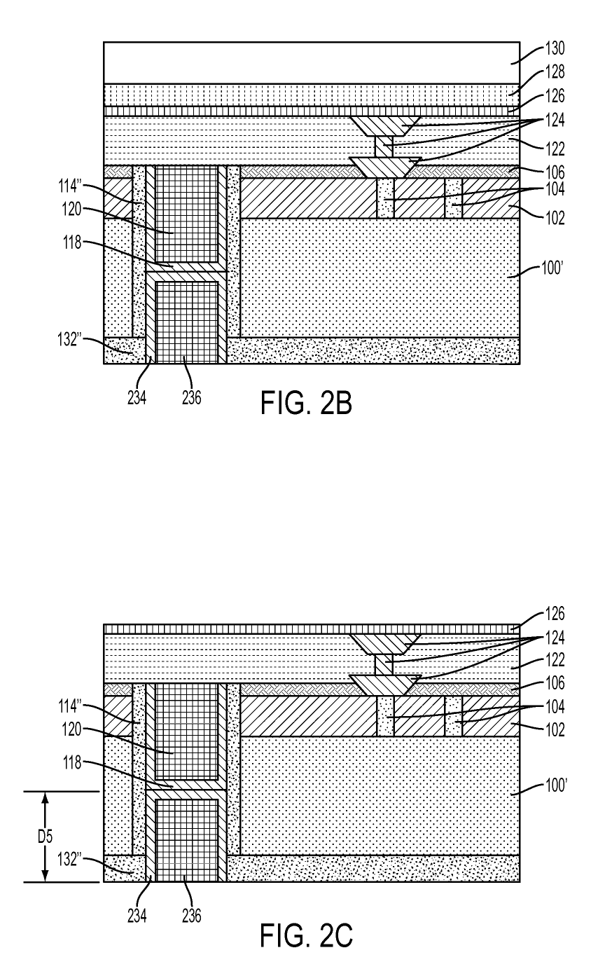

FIGS. 1A through 1M schematically illustrate a process flow for fabricating a TSV structure, according to an exemplary embodiment.

Adverting to FIG. 1A, a silicon substrate (or wafer) 100 is provided. Silicon substrate 100 may include elements of an integrated circuit (IC), such as various types of transistors (not shown for illustrative convenience). An interlayer dielectric (ILD) 102 is formed on the silicon substrate 100 to fill a space between the elements on the wafer and to provide a surface for subsequently formed metallization layers. Contacts or electrical connections 104 between elements on the wafer and the subsequently formed metallization layers can be formed of tungsten through ILD 102, followed by a tungsten chemical mechanical polish (CMP). A hard mask layer 106, such as a nitride hard mask layer is formed over the ILD 102 and connections 104. A photo resist (PR) layer 108 is formed on the hard mask layer 106, and an opening 110 is then formed in the PR layer 108.

As shown in FIG. 1B, an etch process can be performed to etch through the hard mask layer 106, the ILD 102, and into the silicon substrate 100 to form a TSV hole 112. TSV hole 112 is formed partially through silicon substrate 100, and does not extend through to a lower surface of the silicon substrate 100, as shown in FIG. 1B. It should be noted that the TSV hole described herein can be considered as the hole extending within the silicon substrate 100, or as the hole that extends through the ILD 102 and within the silicon substrate 100, or as the hole that extends through the hard mask layer 106, through the ILD 102, and within the silicon substrate 100. The PR layer 108 is then stripped, as shown in FIG. 1C.

The TSV hole 112 can be formed with a diameter greater than or equal to 1 micron (μm), for example in a range from 1 μm to 50 μm, depending upon on the application. The TSV hole 112 can be formed with a depth in a range from 5 μm to 400 μm. By contrast, the contacts 104 can be very small, for example, with a diameter from 20 nanometers (nm) to 200 nm, and depth ranging from 100 nm to 1000 nm.

In FIG. 1D, an isolation layer 114 is formed, for example, by depositing a layer of oxide material. The isolation layer 114 can have a thickness in a range from 20 nm to 200 nm. The material of the isolation layer can be silicon oxide such as tetraethyl orthosilicate (TEOS), and can be formed by a high aspect ratio process (HARP), or high-density plasma (HDP) process.

As shown in FIG. 1E, a dummy plug 116 is formed in a lower via hole portion of the TSV hole 112 such that the dummy plug 116 partially fills the TSV hole 112. The dummy plug 116 is formed of a dielectric material, such as an oxide material, a polysilicon material, polymer material, a flowable oxide material, or other dielectric material.

In one embodiment, the dummy plug 116 is formed by partially filling the TSV hole 112 with a dielectric material, for example by depositing the dielectric material in the TSV hole 112 to a depth D1 and then curing the dielectric material. The depth D1 is at least ⅓ of a total depth D2 of the TSV hole 112 for example ½ of the total depth D2 of the TSV hole 112. The dielectric material can be deposited, for example, by a spin-on-glass method, a spin-on-coating method, a sol-gel method, etc. Once the dielectric material is deposited within the TSV hole 112 to the desired depth, the dielectric material can be cured, for example, at a temperature below 500° C., to complete formation of the dummy plug 116.

In another embodiment, the dummy plug 116 is formed by filling the TSV hole 112 with the dielectric material by depositing the dielectric material in the TSV hole 112 to a depth that greater than or equal to the total depth D2, curing the dielectric material, and then removing a portion of the dielectric material to achieve a desired final depth D1. The final depth D1 is at least ⅓ of a total depth D2 of the TSV hole 112, for example ½ of the total depth D2 of the TSV hole 112. The dielectric material can be deposited, for example, by a chemical vapor deposition (CVD) method, a spin-on-glass method, a spin-on-coating method, a sol-gel method, etc. Once the dielectric material is deposited within the TSV hole 112, the dielectric material can be cured, for example, at a temperature below 500° C. Then, an etching process is performed to achieve the desired final depth D1. Either a dry etch process or a wet etch process can be performed.

As shown in FIG. 1F, a liner material 118 is deposited within the TSV hole 112 and on top of the dummy plug 116, and a conductive material 120, such as copper, is deposited within the TSV 112 on the liner material 118. One or more planarization processes, such as copper electrochemical planarization and CMP, are performed on an upper surface down to hard mask layer 106 to planarize upper surfaces of the liner material 118, the conductive material 120, and isolation layer to form isolation layer 114′. Thus, a first via portion having a depth of D3 and including conductive material 120 (or conductive material 120 and liner material 118) is formed in an upper portion of TSV hole 112. The liner material 118 can be formed of tantalum (Ta), tantalum nitride (TaN), titanium (Ti), titanium nitride (TiN), titanium silicon nitride (TiSiN), tungsten nitride (WN), and the like, with a thickness between 2 nm and 200 nm.

As shown in FIG. 1G, conventional back-end-of line (BEOL) processes are performed to form metallization layers (including at least one fat wire and a top metal layer) all shown for illustrative convenience as 124, with interlayer dielectric layers 122 filling spaces within and between the metallization layers, and a thin nitride protective layer 126 over the top metal layer. As shown in FIG. 1H, an adhesive layer 128 is formed on an upper surface, and a support carrier 130 is attached to the adhesive layer in order to perform processes on the lower surface of the silicon substrate 100.

Adverting to FIG. 1I, a lower portion of the silicon substrate 100′ is removed to expose a lower surface of the dummy plug 116. The removal of the lower portion can be performed by backside grinding, thinning, and cleaning processes.

As shown in FIG. 1J, the dummy plug is removed from the lower portion of the TSV hole 112, for example, by a thermal decomposition, dry etch, or wet etch process. Then, a backside isolation layer 132 is formed, for example, by depositing a layer of oxide on the lower surface of substrate 100′, on the lower surface of the liner material 118 and/or conductive material 120 (e.g., if liner material 118 were removed or not used), and on the sidewalls of the lower portion of the TSV hole 112. Layer 132 may be formed thick, for example to a thickness of 50 nm to 500 nm, on the back surface of substrate 100′, and thin, for example to a thickness of 10 nm to 100 nm, in the lower portion of TSV hole 112.

As shown in FIG. 1K, a backside etch is performed to expose liner material 118, leaving backside isolation layer 132′. The backside etch will also thin the sidewall isolation and the isolation layer on the lower surface of substrate 100′. A dry etch process may be employed to leave a thicker sidewall isolation, as compared to a wet etch process, shown in FIG. 2A, as will be discussed later

Adverting to FIG. 1L, a liner material 134 is deposited within the lower portion of the TSV hole 112, and a conductive material 136, such as copper, is deposited to fill the remainder of the lower portion of the TSV 112. One or more planarization processes, such as copper electrochemical planarization and CMP, are performed on a lower surface to planarize lower surfaces of the liner material 134 and the conductive material 136 down to backside isolation layer 132′. Thus, a second via portion having a depth of D4 and including conductive material 136 (or conductive material 136 and liner material 134) is formed in a lower portion of TSV hole 112. The liner material 134 can be formed of Ta, TaN, Ti, TiN, TiSiN, WN, and the like, with a thickness between 2 nm and 200 nm.

As shown in FIG. 1M, the adhesive layer and the support carrier are then removed from the upper surface. The wafer may then be bonded and electrically connected to another semiconductor wafer.

FIGS. 2A through 2C schematically illustrate a process flow for fabricating a TSV structure using alternative steps to the steps shown in FIGS. 1K through 1M, according to an exemplary embodiment. Accordingly, following the process discussed with regard to FIG. 1J, a backside wet etching process is performed to form the structure shown in FIG. 2A. The wet etching process results in thinner sidewall isolation, as compared to the dry etching process. Thus, the backside wet etch results in backside isolation layer 132″, as shown in FIG. 2A, as the lower surface of the liner material 118 and/or conductive material 120 is exposed.

As shown in FIG. 2B, a liner material 234 is deposited within the lower portion of the TSV hole 112, and a conductive material 236, such as copper, is deposited to fill the remainder of the lower portion of the TSV 112. One or more planarization processes, such as copper electrochemical planarization and CMP, are performed on a lower surface to planarize lower surfaces of the liner material 234 and the conductive material 236 down to backside isolation layer 132″. Thus, a second via portion having a depth of D5 and including conductive material 236 (or conductive material 236 and liner material 234) is formed in a lower portion of TSV hole 112.

The processes shown in FIGS. 1A through 1M and FIGS. 2A through 2C provide for the formation of a TSV that includes two via portions formed in a via hole 112 in a silicon substrate. A first via portion is formed of a first conductive material 120 extending to a first surface of the silicon substrate, and a second via portion is formed of a second conductive material 136, 236 extending to a second surface of the silicon substrate, and the second via portion is electrically conductively connected to the first via portion.

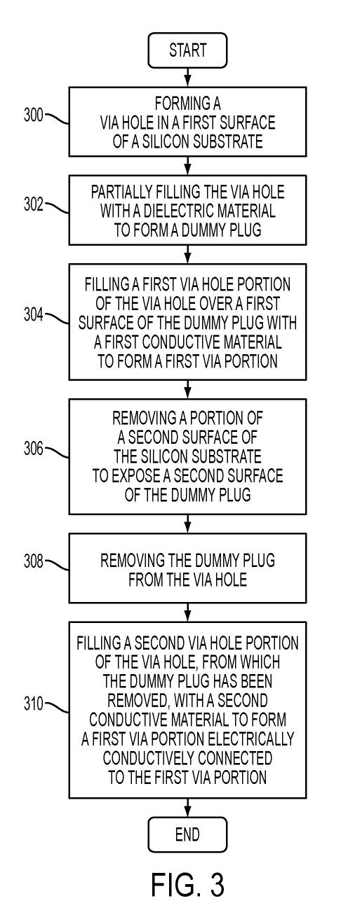

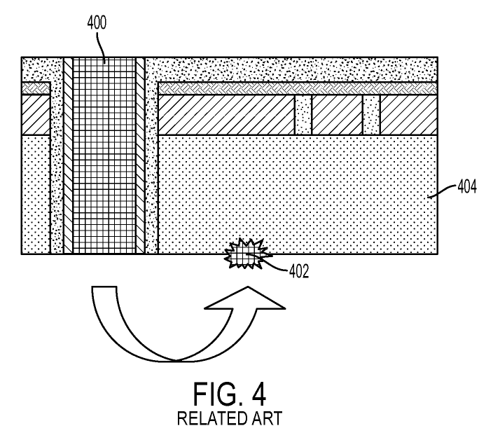

FIG. 3 shows a flowchart of a process flow for fabricating a TSV structure, according to an exemplary embodiment. In step 300, a via hole is formed in a first surface of a silicon substrate. In step 302, the via hole is partially filled with a dielectric material to form a dummy plug. In step 304, a first via hole portion of the via hole is filled over a first surface of the dummy plug with a first conductive material to form a first via portion.

In step 306, a portion of a second surface of the silicon substrate is removed to expose a second surface of the dummy plug. In step 308, the dummy plug is removed from the via hole. In step 310, a second via hole portion of the via hole, from which the dummy plug has been removed, is filled with a second conductive material to form a second via portion electrically conductively connected to the first via portion.

Thus, a method is advantageously provided that includes forming a via hole in a first surface of a silicon substrate, forming a dummy plug in a lower portion of the via hole, forming a first via portion using a first conductive material in an upper portion of the via hole, removing the dummy plug from the lower portion of the via hole, and forming a second via portion using a second conductive material in the lower portion of the via hole, wherein the second via portion is electrically conductively connected to the first via portion.

Embodiments of the invention provide numerous advantages. For example, with such embodiments, there is no concern for backside copper contamination, as can occur in conventional via-middle schemes, in which a copper TSV will be exposed during the backside thinning and cleaning, and the exposed copper may then contaminate the substrate. Also, the embodiments are very friendly to liner deposition or copper seed deposition, and copper electromechanical planarization, because the aspect ratio of the TSV is reduced by half, which provides significant advantages to solve the TSV metallization challenges. Also, compared with a conventional via-last scheme, embodiments of the invention can solve the punch-through issues, because the TSV etch is conducted before the back-side processing. Further, embodiments of the invention are self-aligned and do not require an additional TSV mask.

The embodiments of the present disclosure can achieve several technical effects, particularly in forming cost effective semiconductor TSV structures with high reliability, and manufacturing throughput. Devices formed in accordance with embodiments of the present disclosure enjoy utility in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a via hole in a first surface of a substrate;
partially filling the via hole with a dielectric material;
filling the remainder of the via hole with a first conductive material;
removing a portion of a second surface of the substrate to expose the dielectric material;
removing the dielectric material from the via hole; and
filling a the via hole with a second conductive material electrically conductively connected to the first conductive material.

2. The method according to claim 1, comprising partially filling the via hole with the dielectric material by:
filling the via hole with the dielectric material; and
etching the dielectric material to remove a portion of the dielectric material from the via hole.

3. The method according to claim 1, comprising partially filling the via hole with the dielectric material by depositing the dielectric material in the via hole to a depth of at least ⅓ of a total depth of the via hole.

4. The method according to claim 3, wherein the depth is about ½ of the total depth of the via hole.

5. The method according to claim 1, further comprising conformally depositing an isolation material in the via hole before partially filling the via hole with the dielectric material.

6. The method according to claim 5, further comprising depositing a liner material in the via hole after partially filling the via hole with the dielectric material.

7. The method according to claim 1, further comprising:
depositing an isolation material in the via hole after removing the dielectric material; and
etching to remove the isolation material from an the first conductive material before filling the via hole with the second conductive material.

8. The method according to claim 7, further comprising depositing a liner material in the via hole before filling the via hole with the second conductive material.

9. The method according to claim 1, wherein the first conductive material and the second conductive material are both copper.

10. A through silicon via comprising:
a first via portion formed of a first conductive material in a first via hole extending into a substrate from a first surface of the substrate; and
a second via portion formed of a second conductive material in a second via hole extending into the substrate from a second surface of the substrate,
wherein the second via portion is electrically conductively connected to the first via portion.

11. The through silicon via according to claim 10, wherein the first via portion extends into the substrate to a depth of at most ⅔ of a total depth of the first and second via holes.

12. The through silicon via according to claim 10, wherein the second via portion extends into the substrate to a depth of at least ⅓ of a total depth of the first and second via holes.

13. The through silicon via according to claim 12, wherein the depth is about ½ of the total depth of the first and second via holes.

14. The through silicon via according to claim 10, further comprising an isolation material provided within the first via hole between the first via portion and the silicon substrate.

15. The through silicon via according to claim 14, further comprising a liner material provided within the via hole between the first via portion and the isolation material.

16. The through silicon via according to claim 10, further comprising an isolation material provided within the second via hole between the second via portion and the silicon substrate.

17. The through silicon via according to claim 16, further comprising a liner material provided within the second via hole between the second via portion and the isolation material.

18. The through silicon via according to claim 10, wherein the first conductive material and the second conductive material are both copper.

19. A method comprising:
forming a via hole in a first surface of a silicon substrate;
conformally depositing an isolation material in the via hole;
forming a dummy plug in a lower portion of the via hole;
depositing a liner material in an upper portion of the via hole;
forming a first via portion using a first conductive material in the upper portion of the via hole;
removing the second surface of the silicon substrate to expose a back surface of the dummy plug;
removing the dummy plug from the lower portion of the via hole;
forming an isolation material on the sidewalls of the lower portion of the via hole;
depositing a liner material in the lower portion of the via hole; and
forming a second via portion using a second conductive material in the lower portion of the via hole,
wherein the second via portion is electrically conductively connected to the first via portion.

20. The method according to claim 19, further comprising bonding a support carrier to the first surface of the silicon substrate prior to removing the second surface of the silicon substrate.
